(19) United States
(12) Patent Application Publication
(10) Pub. No.: US 2003/0121898 A1
(43) Pub. Date: Jul. 3, 2003

(54) Heated vacuum support apparatus

(76) Inventors: Tom Kane, Santa Cruz, CA (US); Robert Jeffrey Bailey, Santa Cruz, CA (US); Sam Kurita, Scotts Valley, CA (US); Kris Veeck, Santa Cruz, CA (US)

Correspondence Address: DORSEY & WHITNEY LLP, INTELLECTUAL PROPERTY DEPARTMENT, 4 EMBARCADERO CENTER, SUITE 3400, SAN FRANCISCO, CA, 94111, US

(21) Appl. No.: 10/303,035

(22) Filed: Nov. 22, 2002

Related U.S. Application Data
(60) Provisional application No. 60/333,447, filed on Nov. 26, 2001.

(51) Int. Cl. H05B 1/00; C23F 1/00; C23C 16/00

(52) U.S. Cl. 219/200; 156/345.52; 118/725

(57) ABSTRACT

A wafer support apparatus is provided which comprises a support puck and one or more heaters coupled to the support puck for providing uniform temperature distribution across the surface of the support puck and the wafer surface. The one or more heaters are independently controllable. The wafer support apparatus may further comprise an insulation ring disposed between the support puck and a cooler housing to decouple the support puck from the housing.

### RELATED APPLICATIONS

This application claims priority to the U.S. Provisional Patent Application Serial No. 60/333,447, filed Nov. 26, 2001, the disclosure of which is hereby incorporated by reference in its entirety.

### FIELD OF THE INVENTION

The present invention relates generally to the field of semiconductor equipment and processing. More specifically, the present invention relates to an apparatus and method for supporting a semiconductor wafer or substrate during processing.

### BACKGROUND OF THE INVENTION

Wafer processing systems and methods are widely used in the manufacture of semiconductors and integrated circuits. One particular type of wafer processing system utilizes chemical vapor deposition (CVD) to deposit films or layers on the surface of a substrate as a step in the manufacture of semiconductors and integrated circuits. A variety of different CVD systems are used in the art. For example, films may be deposited using low pressure CVD (LPCVD) systems, atmospheric pressure CVD (APCVD) systems or different types of plasma enhanced CVD (PECVD) systems. In general, all such systems employ a deposition chamber where certain injected gaseous chemicals react and deposit a layer of material on the surface of the substrate. Many types of materials may be deposited, with dielectrics such as oxides and doped oxides being a typical example.

For proper operation of the system, and in particular to deposit a film of desired quality and repeatability, the support of the semiconductor wafer or substrate is important. Substrates are typically supported within the deposition chamber by a wafer support or chuck. It is important to provide substantially uniform heating and cooling of the wafer during processing. Non-uniformities during the heating of the wafer can lead to a non-uniform film formed on the surface of the wafer. While improvement of chuck designs have been made, prior art vacuum chucks have shown limitations such as problems associated with a single piece support puck and temperature control. Accordingly, improvements are needed.

### SUMMARY OF THE INVENTION

A vacuum wafer support apparatus is provided which comprises a support puck and one or more heaters coupled to the support puck for providing uniform temperature distribution across the surface of the support puck and the wafer surface. The one or more heaters are independently controllable.

In one embodiment, the heaters are disposed in concentric outer and inner heating regions in an insulative body and independently controllable. In another embodiment, the outer heating region is further divided into one or more heating zones which are independently controllable.

In another embodiment, the vacuum wafer support apparatus further comprises an insulation ring disposed between the support puck and a cooler housing to thermally decouple the support puck from the housing. The insulation ring is preferably made of quartz. The quartz insulation ring reduces radial heat loss from the support puck thus facilitating steady and uniform temperature distribution across the support puck. The quartz insulation ring reduces the cost of the support puck by reducing the outer diameter of the puck and using a less expensive material for the outermost piece.

### BRIEF DESCRIPTION OF THE DRAWINGS

Other objects and advantages of the present invention become apparent upon reading of the following detailed description of the invention and upon reference to the drawings in which:

FIG. 1 is a partial cross sectional view of the support apparatus according to one embodiment of the present invention.

FIG. 2 is a cross sectional view of the support apparatus according to another embodiment of the present invention.

FIG. 3 is an exploded assembly view of the support apparatus according to one embodiment of the present invention.

FIG. 4 is a top view of the heaters showing two heating regions according to one embodiment of the present invention.

FIG. 5 is a top view of the heaters showing five heating zones according to another embodiment of the present invention.

FIG. 6 is a schematic showing the substantially uniform temperature profile on a wafer carried by the support apparatus of the present invention having five heating zone control.

FIG. 7 is a schematic showing the substantially uniform temperature profile on the wafer carried by the support apparatus of the present invention having five heating zone control and a quartz insulating ring.

FIGS. 8A and 8B show the film uniformity for undoped silicate glass (USG) films on the wafer carried by the support apparatus of the present invention having two heating region control and five heating zone control respectively.

### DETAILED DESCRIPTION OF THE INVENTION

The present invention provides an apparatus and method for supporting a semiconductor wafer or substrate during processing. More particularly, the present invention provides a heated vacuum support apparatus that promotes improved temperature uniformity during processing of the substrate.

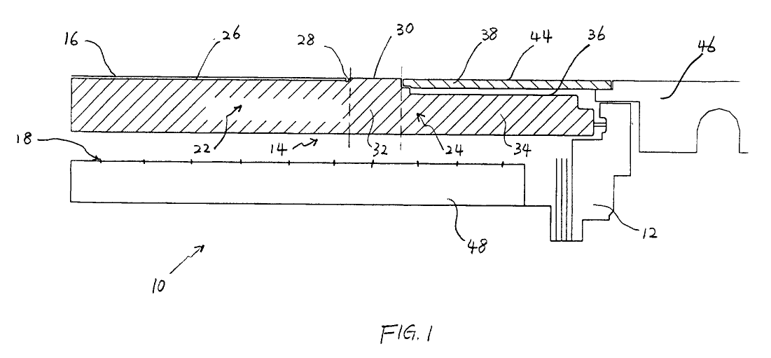

Referring to FIGS. 1 to 5, the vacuum support apparatus 10 of the present invention will now be described. In general, the vacuum support apparatus 10 includes a housing 12, a support puck or body 14 disposed in the housing 12 for supporting a substrate 16 thereon, and one or more heaters 18 coupled to the support puck 14 for heating the support puck 14 to provide uniform temperature distribution across the surface of the substrate 16.

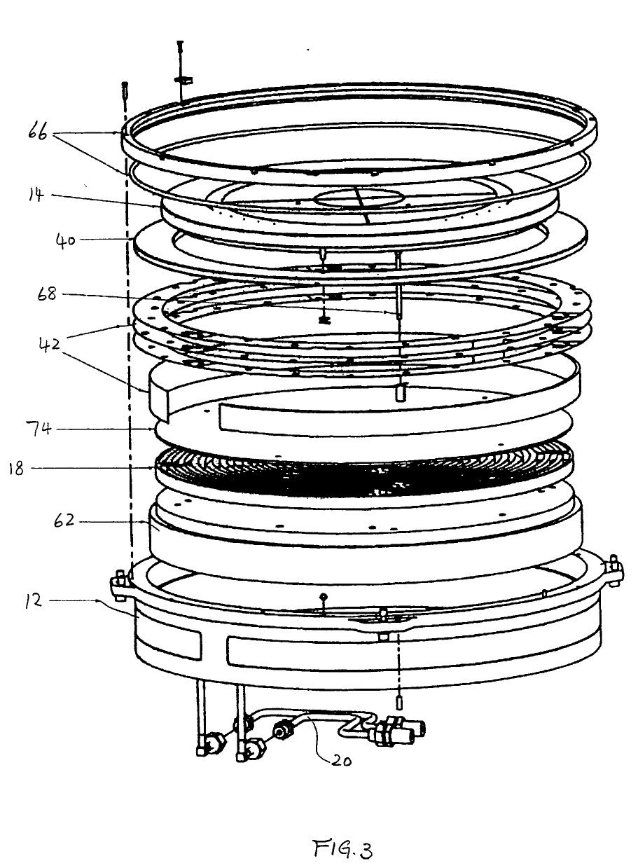

Housing 12 can be made of any mechanically robust and chemically and thermally stable materials. Housing 12 is typically temperature controlled to provide a set reference temperature for heating and cooling of the substrate and to ensure an appropriate operating environment for the components of the vacuum support apparatus 10. For example, housing 12 is preferably cooled by a cooling media such as water supplied by line 20, as shown in FIG. 3.

Support puck 14 includes a first inner portion 22 for supporting the substrate 16 thereon and a second outer portion 24 coupled to housing 12 and other components of the support apparatus 10. The first inner portion 22 has a planar surface 26 having a configuration and dimension suitable for supporting the substrate 16. Specifically, for supporting an annular wafer, the planar surface 26 of the first inner portion 22 preferably has an annular configuration. For instance, the first inner portion 22 of the support puck 14 can be sized to support both 200 mm and 300 mm wafers. Preferably the planar surface 26 of the first portion 22 is defined to have a recess 28 with respect to the second outer portion 24 for reasons described below.

The second outer portion 24 includes a planar surface 30 having a height preferably such that the top surface of the substrate 16 is substantially coplanar with the planar surface 30 when the support apparatus 10 is in operation and use. In one embodiment as shown in FIG. 1, the second outer portion 24 is provided with a first end 32 proximate to the periphery of the first inner portion 22, and a second end 34 coupled to housing 12 and other components of the support apparatus 10. The first end 32 has the same planar surface 30. The second end 34 has a planar surface 36 having a height lower than the first end surface 30 for receiving a deposition ring 38 as described below.

Support puck or body 14 is preferably made of materials that are mechanically robust and chemically and thermally stable. Support puck 14 is preferably made of non-metallic insulating materials that resist corrosive fluids and does not create any contaminating particles to the processed substrate. Ceramic such as aluminum nitride (AlN) is a preferred material for the support puck. Aluminum nitride (AlN) provides for an excellent thermal conductor at high temperatures and has a much lower coefficient of thermal expansion compared to most metallic materials. The AlN puck body can provide excellent chuck and wafer temperature uniformity, while allowing the use of less expensive, low-precision heating elements as described below. The AlN chuck body is highly inert to fluorine-containing gases used for periodic cleaning of the deposition region.

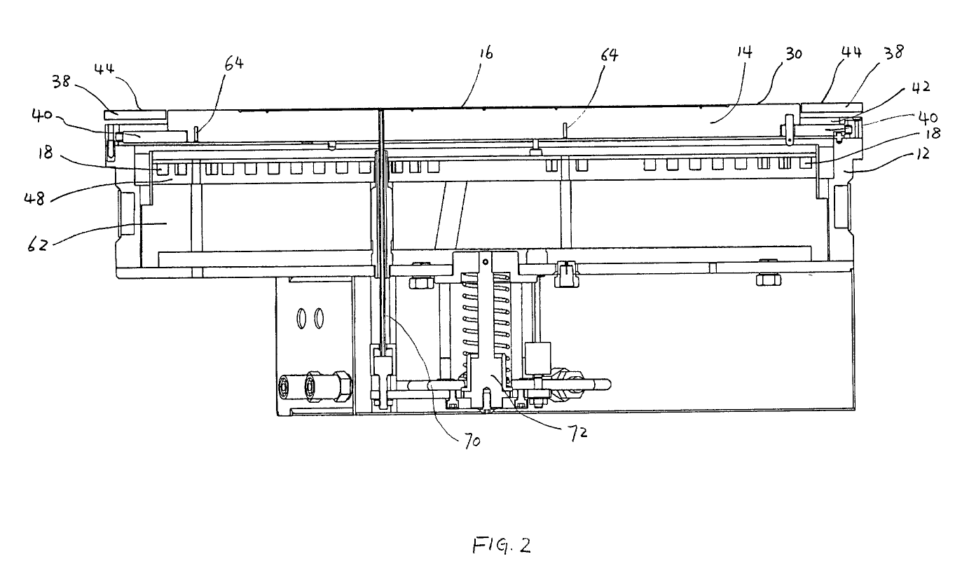

The support puck 14 is preferably insulated from cooler plate 46 and housing 12 to provide the substrate 16 with temperature uniformity and promote heater efficiency. In one embodiment, as shown in FIG. 2, an insulation ring 40 is used to thermally decouple the support puck 14 from the housing 12. Specifically, the insulating ring 40 is disposed surrounding the periphery of the support puck 14 and coupled to the housing 12. The insulation ring 40 can be arranged in close contact to the periphery of the support puck 14, or preferably is spaced from the periphery of the support puck 14 at a distance from about 1″ to about 1.5″ (about 25 to about 38 mm) for improved insulation effect.

Above the insulation ring 40 is disposed a deposition ring 38 which is coupled to the cooling plate 46. Preferably the deposition ring 38 is spaced above the insulation ring 40 by an air gap to minimize thermal contact. Preferably one or more thermal shields 42 are disposed between the insulation and deposition rings 38 and 40, as shown in FIGS. 2 and 3. After assembly of the support apparatus 10, the deposition ring 38 has a planar surface 44 substantially coplanar with the planar surface 30 of the second portion 24. Alternatively, in the embodiment where the second portion 24 of the puck body 14 has first and second ends 32 and 34, as shown in FIG. 1, the second end 34 can be coupled to housing 12 directly by any suitable means. Above the second end 34 is disposed the deposition ring 38 that is coupled to plate 46 and first end 32 of the second portion 24. Preferably the deposition ring 38 is spaced above the second end 34 of the second portion 24 to minimize thermal contact. The deposition ring 38 preferably has a surface 44 substantially coplanar with the first end surface 30 of the second outer portion 24 after the support apparatus 10 is assembled.

The insulating ring 40 can be made of any suitable insulating materials. Preferably insulation ring 40 is made of quartz. The deposition ring 38 can be made of any chemical and thermal stable insulating materials and is preferably made of the same material as the puck body 14 such as aluminum nitride (AlN). The insulation and deposition rings 40 and 38 reduce radial heat loss from the support puck 14 and thus facilitating steady and uniform temperature distribution across the planar surface 26 of the first portion 22 on which the substrate 16 is supported. The insulation and deposition rings 40 and 38 also decrease power consumption by minimizing heat loss to the cooled housing and plate 12 and 46. The insulation ring 40 further improves mechanical reliability of the support puck 14 by reducing tangential stresses. The quartz insulation ring 40 reduces the cost of the ceramic support puck 14 by reducing the outer diameter of the puck 14 and using a less expensive material for the outermost piece.

One or more heaters 18 are coupled to the support puck 14 to provide steady and uniform temperature distribution across the first portion 22 of the support puck 14 and the substrate 16 supported thereon. The one and more heaters 18 can be incorporated into the support puck 14, or preferably is incorporated in an insulation body 48 separated from the support puck 14 by an air gap. Each of the one or more heaters 18 is independently controlled as described below.

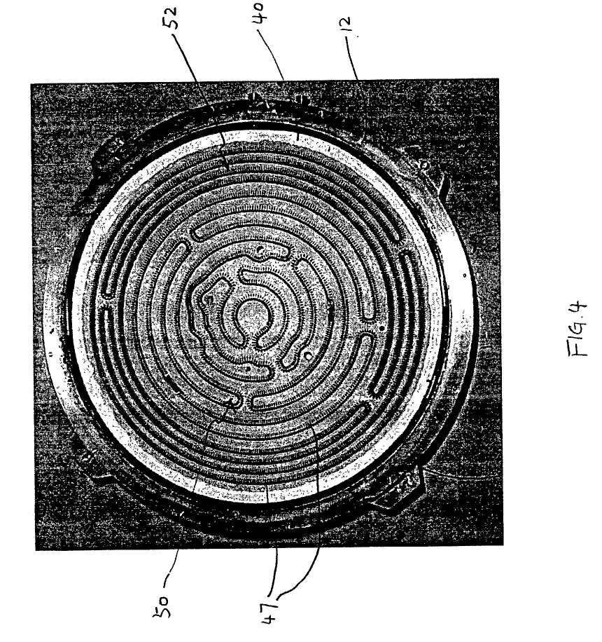

Heaters 18 are comprised of any suitable heating elements 47 such as resistive coils, tubular or thick films shown in FIG. 4. In one embodiment, as shown in FIG. 4, the heating elements 47 are disposed in an insulation body 48 which forms concentric annular inner and outer heating regions 50 and 52. The heating elements 47 in the inner and outer regions 50 and 52 are independently controlled. The insulation body 48 for embedding heating elements 47 can be any thermally insulating material such as quartz. The heating elements 47 such as resistive wires can be embedded in the quartz insulation body 48 in a configuration of a plurality of concentric rings. While a specific configuration for heating elements is described, the present invention is not so limited. Other configuration for the heating elements in one or more heating regions can be employed.

Preferably the inner heating region 50 is substantially adjacent to the first portion 22 of the support puck 14. The outer heating region 52 is substantially adjacent to the second outer region 24 of the support puck 14. However, other disposition of the heaters 18 are possible and the present invention is not so limited.

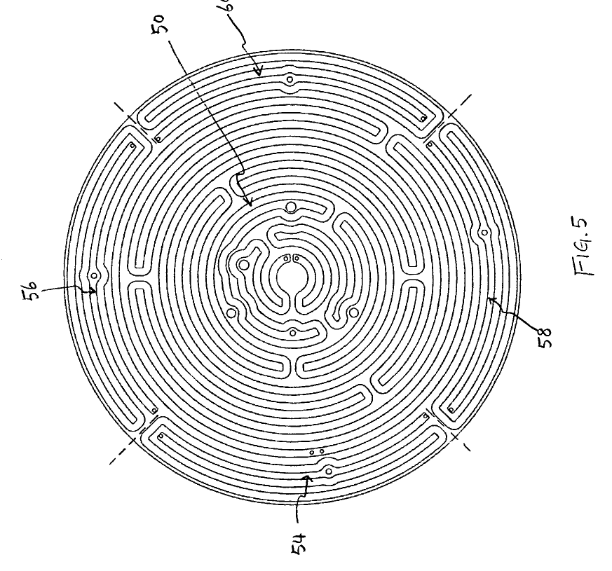

In one embodiment, the outer heating region 52 is further divided into two or more heating zones, as shown in FIG. 5. The heating elements 47 in each of the two or more heating zones of the outer region 52 are independently controlled to mitigate asymmetric conditions in the process environment. For example, as shown in FIG. 5, the outer region 52 is preferably divided into four quadrant zones 54, 56, 58 and 60. The heating element 47 in each of the quadrant zones 54 through 60 is independently controlled. The four heating zones in the outer region 52 and one heating zone in the inner region 50 provide five heating zones that are independently controlled. Conventional temperature controllers available in the art such as Eurotherm and Watlow can be used to independently control the heating regions or zones. Each independent temperature controller provides three mode (proportional, integral, and derivative) feedback control to the element firing circuitry. Phase angle firing controllers or zero-crossover solid state relays are typically utilized.

Heaters 18 are preferably insulated from the housing 12 to minimize heat loss to surfaces other than the support chuck 14. Non-metallic insulating body 62 and radiation shields 42 can be used to insulate the heaters 18 from housing 12, as shown in FIG. 3.

The heaters 18 in the outer and inner regions, or in the multiple heated zones are independently controlled via feedback from thermalcouples 64 disposed in the support puck 14, as shown in FIG. 2, to temperature controllers (not shown) coupled to the heaters. Multiple heaters or heated zones greatly improve the temperature uniformity of the substrate by providing localized compensation for wafer non-uniformity due to external factors such as localized gas flows, asymmetries in conduction paths or inconsistencies in the substrate to support puck contact. Multiple heated zones reduce within-wafer and wafer-to-wafer temperature variability.

The support apparatus further includes retaining rings 66 and heater cover 74 as shown in FIGS. 2 and 3. Substrate clamping vacuum lines 68 are provided for providing vacuum to chuck the substrate 16 to the chuck body 14 in operation as described below. Lift pins and mechanism 70 and 72 are provided for lifting the substrate 16 from the support puck 14 in operation as described below.

In operation, the support apparatus 10 is moved up and down via lift mechanism 72 to position the support apparatus 10 within a deposition chamber. The substrate 16 is lifted and placed on the support puck 14 by lift pins 70 and secured to the support puck 14 by means of vacuum. The substrate 16 is preferably adhered or chucked to the first portion 22 by a pressure differential created between the substrate 16 and the support chuck 14 in excess of the vacuum condition maintained in a chamber where the support apparatus 10 is disposed. That is, when the substrate 16 is chucked to the support puck 14, the pressure between the substrate 16 and the support puck 14 is less than the pressure in the chamber. To create this pressure differential, the support chuck 14 is provided with vacuum channels 68 which are in fluid communication with a vacuum supply (not shown).

When the substrate 16 is secured on the support puck 14, the substrate 16 is substantially coplanar with the periphery surfaces surrounding the substrate. The heating elements 47 in the two heating regions or multiple heating zones are independently controlled so that the substrate surface and its perimeter surfaces have substantially the same temperature.

Of advantage, the wafer support apparatus of the invention promotes substantially uniform flow of the process or reactant gases on the surface of the wafer during processing to facilitate deposition of good quality films on the surface of the wafer. The support provides an integrated wafer perimeter surfaces which are substantially coplanar with the wafer surface and are heated to substantially the same temperature as the wafer. Accordingly the flowing process gases experience a highly uniform flow and thermal environment at all positions across the wafer and support. In addition, transitional deposition ring around the support puck perimeter reduce the surface temperatures smoothly to near-ambient.

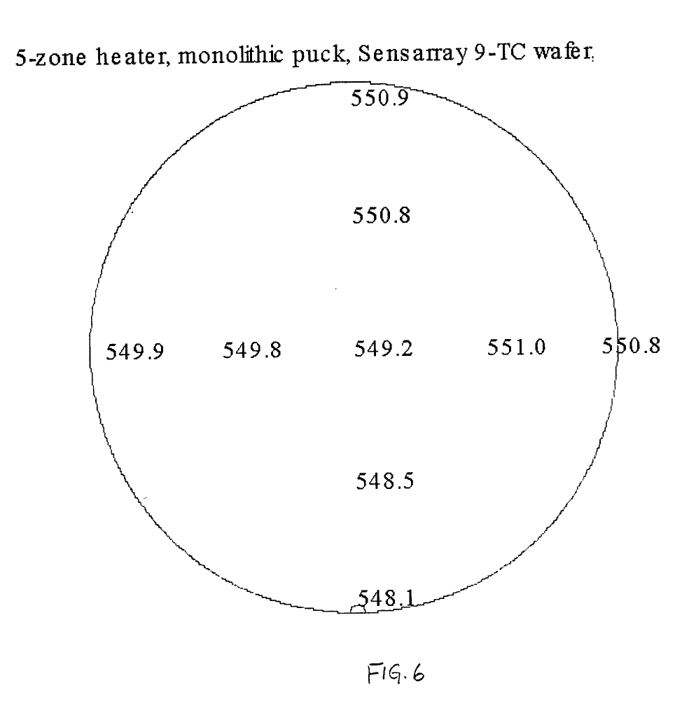

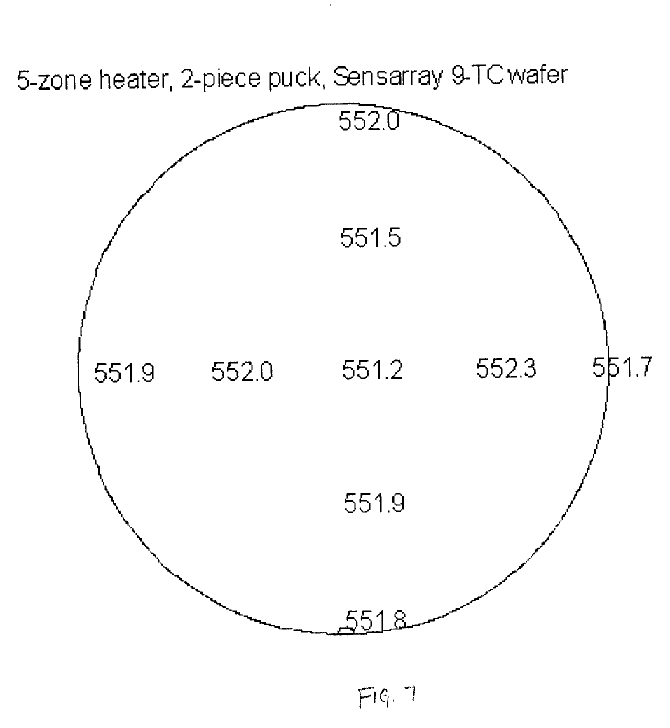

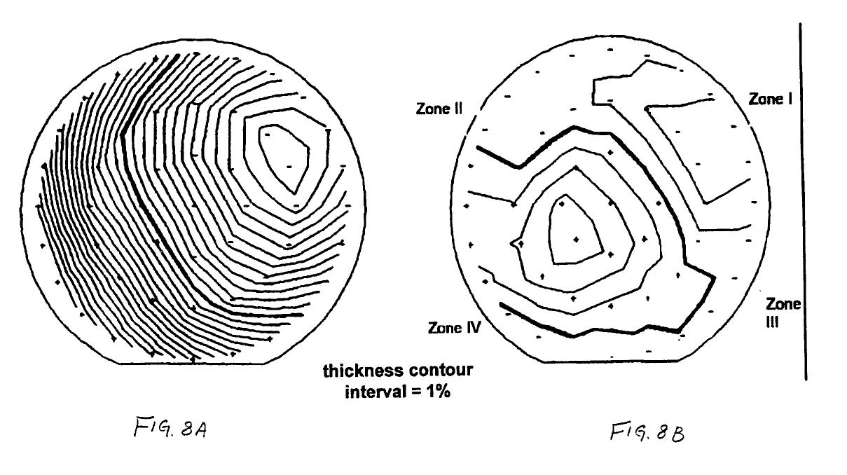

FIGS. 6 and 7 show the temperature distribution achieved with the vacuum support apparatus of the present invention. As shown in FIGS. 6 and 7, a substantially steady and uniform temperature distribution on the wafer was achieved with the five heating zone control. The temperature is measured in the APNext module chamber. The vacuum support apparatus 10 with quartz insulation ring 40 provided even better temperature distribution across the wafer surface as shown in FIG. 7. FIG. 8 shows the good film uniformity for undoped silicate glass (USG) films on the wafer carried by the vacuum support apparatus of the present invention during processing. A film thickness uniformity of 8.8% 1σ was achieved with the vacuum support apparatus having concentric outer and inner heating region control. A film thickness uniformity of 1.6% 1σ was achieved with the vacuum support apparatus having five heating zone control.

As described above, a support apparatus with improved uniformity in heating has been provided by the present invention. The foregoing description of specific embodiments of the invention have been presented for the purpose of illustration and description. They are not intended to be exhaustive or to limit the invention to the precise forms disclosed, and obviously many modifications, embodiments, and variations are possible in light of the above teaching. It is intended that the scope of the invention be defined by the claims appended hereto and their equivalents.

We claim:

1. A vacuum support apparatus, comprising:
a support puck having a surface; and
one or more heaters coupled to said support puck for providing uniform temperature distribution across the surface of said support puck,
wherein said one or more heaters are independently controllable.

2. The vacuum support apparatus of claim 1 wherein said support puck is made of aluminum nitride.

3. The vacuum support apparatus of claim 1 wherein said one or more heaters are comprised of heating elements disposed in one or more heating regions in an insulative body, said heating elements in the one or more heating regions being independently controllable.

4. The vacuum support apparatus of claim 3 wherein said one or more heaters are comprised of heating elements disposed in concentric outer and inner heating regions in the insulative body and being independently controllable.

5. The vacuum support apparatus of claim 4 wherein said heating elements within said outer heating region are disposed in one or more heating zones and being independently controllable.

6. The vacuum support apparatus of claim 5 wherein said heating elements within said outer heating region are disposed in four quadrant zones.

7. The vacuum support apparatus of claim 3 wherein said heating elements are comprised of resistive coils.

8. The vacuum support apparatus of claim 3 wherein said concentric inner region has an inner diameter of about from 180 to 220 mm and said outer region has an outer diameter of about from 185 to 305 mm.

9. The vacuum support apparatus of claim 3 wherein said concentric inner region has an inner diameter of about from 280 to 320 mm and said outer region has an outer diameter of about from 285 to 406 mm.

10. The vacuum support apparatus of claim 8 wherein said support puck has a periphery and said vacuum chuck further comprises an insulation member surrounding the periphery for insulating the support puck from a housing enclosing the support puck.

11. The vacuum support apparatus of claim 10 wherein said insulation member is made of quartz.

12. The vacuum support apparatus of claim 1 wherein said one or more heaters are spaced from said support puck by an air gap.

13. An apparatus for supporting a wafer, comprising:
a housing;
a support puck disposed within the housing;
an insulating member disposed between the support puck and the housing for insulating the support puck from the housing; and
one or more heaters coupled to said support puck, wherein said one or more heaters are independently controllable; and
a vacuum system for securing said wafer to the support puck.

14. The apparatus of claim 13 wherein said support puck is made of aluminum nitride.

15. The apparatus of claim 13 wherein said insulating member is made of quartz.

16. The apparatus of claim 13 wherein the one or more heaters are comprised of heating elements disposed in one or more heating regions in an insulating body, said heating elements disposed in one or more heating regions are independently controllable.
